(19) United States
(12) Patent Application Publication
(10) Pub. No.: US 2013/0344441 A1
(43) Pub. Date: Dec. 26, 2013

(54) ORGANIC SOLVENT DEVELOPABLE PHOTORESIST COMPOSITION

(71) Applicants: RATNAM SOORIYAKUMARAN, SAN JOSE, CA (US); LINDA K. SUNDBERG, LOS GATOS, CA (US); ANKIT VORA, SAN JOSE, CA (US)

(72) Inventors: RATNAM SOORIYAKUMARAN, SAN JOSE, CA (US); LINDA K. SUNDBERG, LOS GATOS, CA (US); ANKIT VORA, SAN JOSE, CA (US)

(73) Assignee: INTERNATIONAL BUSINESS MACHINES CORPORATION, ARMONK, NY (US)

(21) Appl. No.: 13/530,004

(22) Filed: Jun. 21, 2012

(51) Int. Cl. G03F 7/004; G03F 7/20; C08F 228/04

(52) U.S. Cl. 430/285.1; 430/270.1; 526/243; 430/281.1; 430/325; 430/296

(57) ABSTRACT

Provided is a hydrophobic negative tone developable (NTD) resist composition comprising (a) a hydrophobic polymer having (i) at least one nonpolar acid-stable group; and (ii) at least one nonpolar acid-labile group, and (b) a photoacid generator (PAG) that may or may not be bound to the polymer, wherein a nonpolar aromatic or aliphatic organic hydrocarbon solvent is used to develop the unexposed regions of the NTD resist film and the resist film is not developable in an aqueous base developer, such as 0.26 N TMAH.

### TECHNICAL FIELD

The present invention relates generally to photoresist compositions and more specifically to hydrophobic negative tone developable (NTD) photoresists comprising a hydrophobic polymer and a photo acid generator (PAG), wherein a non-polar aromatic or aliphatic organic hydrocarbon solvent is used to develop the unexposed resist film.

### BACKGROUND OF THE INVENTION

The semiconductor fabrication technique of microlithography defines the high resolution circuitry in a semiconductor device by exposing a photoresist to high energy radiation, such as photons, electrons, or ion beams. A photoresist typically consists of a radiation sensitive polymer, a solvent, and a photoacid generator. In practice, the photoresist is spin coated on a silicon wafer to typically form a 30 to 500 nm thick coating. The coated photoresist film is then exposed patternwise to induce a chemical transformation that renders the solubility of the exposed areas of the film to be different from the solubility of the unexposed areas. The radiation used for exposure is most commonly ultraviolet light at wavelengths of 436, 365, 257, 248, 193 or 13.5 nanometers (nm), or a beam of electrons or ions (also known as “e-beam radiation” or “ion beam radiation,” respectively). After exposure, the photoresist film is developed with a solvent to generate the photoresist image on the wafer. The photoresist is classified as a positive-tone resist (PTR) or a negative-tone resist (NTR) depending on the final image that is created. In positive-tone imaging, the exposed area of the resist film is rendered more soluble in the developer than the unexposed area, whereas in negative-tone imaging, the unexposed area is more soluble in the developer than the exposed area.

While most of the photoresist processing currently being carried out involves PTRs at 193 nm, in the past decade, there has been an increased interest in developing NTRs with the goal of improving the imaging performance and/or the process window of the resist for a particular masking level. For example, in 2001, Brunner and Fonseca (Proc. SPIE, 4345:30 (2001)) explored the optimal process tone for different feature types as a function of resist parameters, such as acid diffusion length and resist contrast, and concluded that narrow trenches are best printed with a negative tone imaging process.

A negative tone imaging process can be achieved by two methods. The first method uses specially designed NTRs, which are developed with the standard tetramethyl ammonium hydroxide (TMAH) developer. Most of the attempts to produce NTRs have used cross-linking systems, which have resulted in NTR films with defects, such as bridging and high line edge roughness (LER), such defects being attributed to the swelling of the resist during the development stage. While PTR technology (similarly developed in standard TMAH developer) for 193 nm applications is highly advanced, attempts to make advanced NTRs for 193 nm applications have had limited success and as a result NTRs are not widely available. The second method is a negative tone development (NTD) process, which uses an organic solvent to reverse the tone of a PTR; with this process, the NTD is a PTR that undergoes a polarity switch. Because of the foregoing shortcomings, instead of developing a new NTR for 193 nm, the current trend in semiconductor fabrication is to use the NTD polarity switch process.

Currently available PTRs are optimized for 193 nm tools with 0.26 N TMAH as the aqueous developer. PTR polymers typically include monomeric units (up to 75 mol %) with polar functionalities, such as phenol, hexafluoro alcohol (HFA), or lactones, that are added to the monomers to help with the TMAH dissolution of the exposed areas. When a PTR bearing these functional groups is used to prepare an NTD resist, the polarity switch is not efficient; the resist goes from being polar to slightly more polar, requiring special developer solvents that dissolve the unexposed polar groups of the polymer while not dissolving the slightly more polar groups of the polymer. This inefficiency often leads to a loss of thickness in the exposed areas of the resist film as well as high roughness and scum (undissolved remaining material at the surface interface). Another shortcoming with the use of PTR resists for NTD applications is the cost associated with the preparation of the resist. The polar components of the PTR are expensive and do not offer any significant advantages to the function of the resulting NTD resist.

### SUMMARY OF THE INVENTION

The present invention overcomes the shortcomings in the art with respect to NTD resists by providing a photoresist composition comprising: (a) a hydrophobic polymer comprising (i) at least one non-polar acid-stable group; and (ii) at least one non-polar acid-labile group, wherein the hydrophobic polymer does not have any polar groups; and (b) a photo acid generator (PAG), wherein upon exposure to radiation, the PAG dissociates to form a photo acid that reacts with the at least one non-polar acid-labile group resulting in increased polarity of the hydrophobic polymer and further wherein upon development with an organic hydrocarbon solvent, unexposed areas of the photoresist composition dissolve and exposed areas of the photoresist composition remain to give a negative tone image on a substrate.

The present invention also provides a photoresist composition, comprising: (a) a hydrophobic polymer comprising (i) at least one non-polar acid-stable moiety and (ii) at least one non-polar moiety capable of increasing polarity of the composition by action of an acid; and (b) a photo acid generator (PAG), wherein upon patternwise exposure of the composition to radiation, exposed regions of the photoresist composition are not developable in 0.26 N TMAH developer.

The present invention further provides a method comprising the steps of: (a) dissolving the hydrophobic polymer-PAG composition of the present invention in a casting solvent; (b) coating a substrate with the dissolved composition of step (a) to produce a resist film; (c) optionally baking the resist film of step (b); (d) exposing the resist film to radiation; (e) optionally baking the resist film of step (d); and (f) developing the resist film with an organic hydrocarbon solvent to dissolve unexposed regions of the film.

In one embodiment of the invention, the at least one non-polar acid-stable group of (a)(i) is selected from the group consisting of Formula I and Formula II:

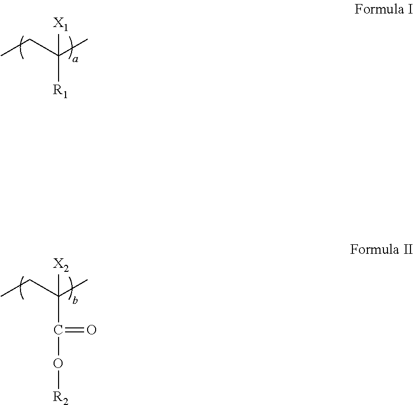

wherein

X1 and X2 are independently selected from the group consisting of H, CH₃, and CF₃;

R1 is selected from the group consisting of aromatic hydrocarbons and substituted aromatic hydrocarbons;

R2 is selected from the group consisting of aromatic hydrocarbons, aliphatic hydrocarbons, substituted aromatic hydrocarbons, substituted aliphatic hydrocarbons, and silicon containing compounds; and

a and b are independently a non-zero integer >1.

In another embodiment of the invention, the at least one non-polar acid-labile group of (a)(ii) is selected from the group consisting of Formula III and Formula IV:

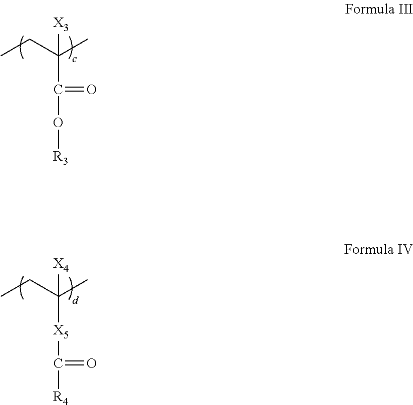

wherein

X3 and X4 are independently selected from the group consisting of H, CH₃, and CF₃;

X5 is a linking group selected from the group consisting of a single bond, aromatic groups, aliphatic groups, substituted aromatic groups, and substituted aliphatic groups.

R3 and R4 are independent acid labile groups; and

c and d are independently a non-zero integer >1.

In a further embodiment of the invention, the at least non-polar one acid stable group of (a)(i) is selected from the group consisting of 2-vinylnapthylene, styrene, adamantyl methylmethacrylate, and isobornyl methacrylate.

In another embodiment, the at least non-polar one acid labile group of (a)(ii) is selected from the group consisting of ethylcyclopentyl methacrylate (ECPMA), methyladamantyl methacrylate (MAdMA), and ethylcyclohexyl methacrylate (ECHMA), ethylcyclooctyl methacrylate (ECOMA), ethyladamantyl methacrylate (EAdMA).

In a further embodiment, the hydrophobic polymer of is selected from the group consisting of poly(2-vinyl naphthalene-co-ethylcyclopentyl methacrylate) (P(2VN-co-ECPMA)); poly(styrene-co-ethylcyclopentyl methacrylate) (P(Sty-co-ECPMA)); poly(2-vinyl naphthalene-co-methyladamantyl methacrylate) (P(2VN-co-MAdMA)); poly(adamantyl methylmethacrylate) (P(AdMMA-co-MAdMA)); and poly(2-vinyl naphthalene-co-methyladamantyl methacrylate-co-triphenylsulfonium 1,1-difluoro-2-(methacryloxyloxy)ethanesulfonate) (P(2VN-co-MAdMA-co-TPS-IMA)).

In other embodiments of the invention, the non-polar acid-stable group is present in the composition in the range of about 10-70 mol %; the non-polar acid-labile group is present in the composition in the range of about 30-70 mol %; and the combination of the non-polar acid-stable group and the non-polar acid-labile group of (a)(ii) is present in the composition in the range of at least 80 mol %.

In another embodiment, the PAG is present in the composition in the range of about 1-15 mol %. Further, the PAG may be bound to the polymer or not bound to the polymer.

In a further embodiment, the substrate is selected from the group consisting of silicon, silicon dioxide, aluminum oxide, sapphire, germanium, gallium arsenide, an alloy of silicon and germanium, and indium phosphide. In a preferred embodiment of the invention, the substrate is silicon.

In another embodiment of the invention, the photoresist is exposed with radiation selected from the group consisting of deep ultraviolet (DUV) radiation (248 nm and 193 nm), extreme ultraviolet (EUV) radiation (13.5 nm), electron beam (e-beam) radiation, and ion beam radiation.

In a further embodiment of the invention, the organic hydrocarbon solvent used to develop the resist film is selected from a non-polar aliphatic solvent and a non-polar aromatic solvent.

In another embodiment, the organic hydrocarbon solvent is selected from the group consisting of mesitylene, xylene, toluene, decane, hexane, and dodecane.

In a further embodiment, exposed regions of the photoresist composition are not developable in an aqueous base developer.

In another embodiment, the photoresist composition has a static water contact angle of at least 80°.

Additional aspects and embodiments of the invention will be provided, without limitation, in the detailed description of the invention, which is set forth below.

### BRIEF DESCRIPTION OF THE DRAWINGS

FIG. 1 shows SEM images of the patterned 1:1 line/space (L/S) P(2VN-co-MAdMA) resist of Example 3 exposed at DUV 248 nm radiation and developed with the NTD solvent mesitylene.

FIG. 2 is a graph showing the contrast curve for the P(AdMMA-co-MAdMA) resist of Example 4 exposed at DUV 193 nm radiation and developed with the NTD solvent mesitylene.

FIG. 3 shows SEM images of the patterned 1:1 L/S P(AdMMA-co-MAdMA) resist of Example 4 exposed at DUV 193 nm radiation and developed with the NTD solvent mesitylene.

FIG. 4 is a graph showing the contrast curve for the PAG-bound P(2VN-co-MAdMA-coTPS-IMA) resist of Example 5 exposed at EUV 13.5 nm radiation and developed with the NTD solvent mesitylene.

FIG. 5 shows SEM images for the patterned 1:1 L/S P(2VN-co-MAdMA-co-TPS-IMA) resist of Example 5 exposed at EUV 13.5 nm radiation and developed with the NTD solvent mesitylene.

FIG. 6 is a graph showing the contrast curve for the P(2VN-co-MAdMA-co-TPS-IMA) resist of Example 5 exposed with e-beam radiation and developed with the NTD solvent mesitylene.

FIG. 7 shows a cross-sectional SEM image for the patterned 1:1 L/S P(2VN-co-MAdMA-co-TPS-IMA) resist of Example 5 exposed with e-beam radiation and developed with the NTD solvent mesitylene.

FIG. 8 is an optical photograph showing the static water contact angle for the P(2VN-co-MAdMA) resist of Example 3.

FIG. 9 shows an cross sectional SEM image for the patterned 1:1 L/S of the PAG-bound P(2VN-co-MAdMA-coTPS-IMA) resist of Example 5 exposed at DUV 248 nm radiation and developed with the NTD solvent mesitylene.

FIG. 10 shows an SEM image of the PAG-bound P(2VN-co-MAdMA-coTPS-IMA) resist of Example 5 exposed at DUV 248 nm radiation and developed with the PTR solvent 0.26 N TMAH.

### DETAILED DESCRIPTION OF THE INVENTION

Set forth below is a description of what are currently believed to be preferred embodiments of the claimed invention. Any alternates or modifications in function, purpose, or structure are intended to be covered by the claims of this application. As used in this specification and the appended claims, the singular forms “a,” “an,” and “the” include plural referents unless the context clearly dictates otherwise. The terms “comprises” and/or “comprising,” as used in this specification and the appended claims, specify the presence of stated features, integers, steps, operations, elements, and/or components, but do not preclude the presence or addition of one or more other features, integers, steps, operations, elements, components, and/or groups thereof.

As used herein, the terms “resist” and “photoresist” are meant to refer to the same composition and thus, the terms are used interchangeably herein.

The term “negative tone resist” and “NTR” refers to a photoresist that is developable with the standard aqueous base developer, 0.26 N TMAH, and produces a negative tone image (where unexposed regions are removed during the development process).

The term “positive tone resist” and “PTR” refers to a photoresist that is developable with the standard aqueous base developer, 0.26 N TMAH, and produces a positive tone image (where exposed regions are removed during the development process).

The terms “negative tone developable resist,” “NTD resist,” and “NTD photoresist,” refer to an organic solvent developable negative tone resist.

Within the context of the present invention, organic solvents that may be used to develop NTD resists may be referred to herein as “NTD solvents.”

The term “deep ultraviolet radiation” or “DUV” is meant to refer to radiation at 248 nm and 193 nm.

The term “extreme ultraviolet radiation” or “EUV” is meant to refer to radiation at 10 to 14 nm, with 13.5 nm being the most commonly used EUV wavelength.

The present invention provides a resist composition comprising a hydrophobic radiation sensitive polymer designed to be developed with an organic hydrocarbon solvent for NTD applications. The NTD resist compositions prepared from the hydrophobic polymers of the present invention have improved properties over the currently used polarity switching PTR compositions, such improved properties including greater polarity switch and reduced thickness loss of the exposed areas of the resist upon development with an organic hydrocarbon solvent. A characteristic of the NTD resists of the present invention is that the resist film is not developable in an aqueous base developers, such as for example, 0.26 N TMAH. Because the NTD resists of the present invention do not form positive tone images when developed in an aqueous base, unlike currently used NTD resists, the inventive NTD resists do not behave like PTRs in aqueous base developer.

In one embodiment, the NTD photoresist composition of the present invention comprises: (a) a hydrophobic polymer comprising (i) at least one non-polar acid-stable group; and (ii) at least non-polar one acid labile group; and (b) a PAG. Importantly and uniquely, the hydrophobic polymer does not have any polar functionalities, such as alcohols, phenols, acids, lactones, anhydrides, fluoroalcohols, amides, sulfonimides, urea, thiourea, quaternary ammonium salts, polyethylene and polypropylene oxide derivatives, silanols, zwitterions, and the like. When the photoresist composition is patternwise exposed to radiation (such as DUV, EUV, e-beam, or ion-beam radiation), the PAG dissociates to form a photo acid that reacts with the at least one non-polar acid-labile group resulting in increased polarity of the hydrophobic polymer. Upon development of the photoresist with an organic hydrocarbon solvent, unexposed areas of the photoresist composition dissolve and the exposed areas of the photoresist composition remain to give a negative tone image on a substrate. An additional unique feature of the invention is that the exposed areas of the photoresist composition are not developable in an aqueous base developer, such as for example, 0.26 N TMAH.

In another embodiment of the invention, the non-polar acid-stable group is selected from the group consisting of Formula I and Formula II:

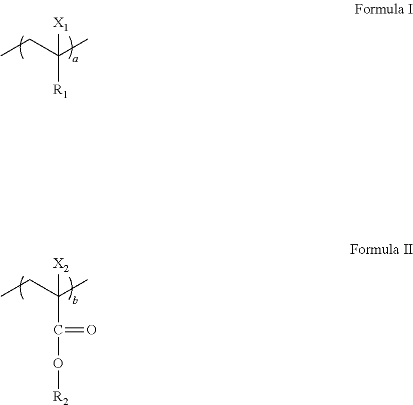

wherein

X1 and X2 are independently selected from the group consisting of H, CH₃, and CF₃;

R1 is selected from the group consisting of aromatic hydrocarbons and substituted aromatic hydrocarbons;

R2 is selected from the group consisting of aromatic hydrocarbons, aliphatic hydrocarbons, substituted aromatic hydrocarbons, substituted aliphatic hydrocarbons, and silicon containing compounds; and

a and b are independently a non-zero integer >1.

In a further embodiment of the invention, the non-polar acid-labile group is selected from the group consisting of Formula III and Formula IV:

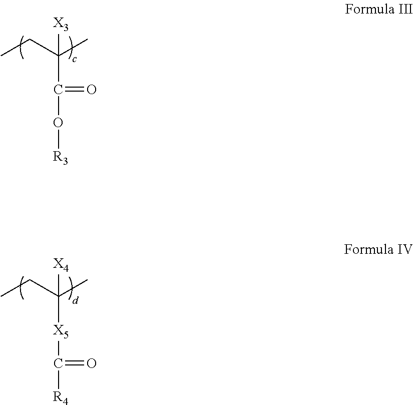

wherein

X3 and X4 are independently selected from the group consisting of H, CH₃, and CF₃;

X5 is a linking group selected from the group consisting of a single bond, aromatic groups, aliphatic groups, substituted aromatic groups, and substituted aliphatic groups.

R3 and R4 are independent acid labile groups; and

c and d are independently a non-zero integer >1.

Examples of the non-polar acid-stable group include, without limitation, 2-vinylnapthylene, styrene, adamantyl methylmethacrylate, isobornyl methacrylate, and the like.

Examples of the non-polar acid-labile group include, without limitation, ethylcyclopentyl methacrylate (ECPMA), methyladamantyl methacrylate (MAdMA), ethylcyclohexyl methacrylate (ECHMA), and the like. Example 1 describes the synthesis of the following five hydrophobic polymers, which may be used to design the NTD resists of the present invention: (1) poly(2-vinyl naphthalene-co-ethylcyclopentyl methacrylate) (P(2VN-co-ECPMA)); (2) poly(styrene-co-ethylcyclopentyl methacrylate) (P(Sty-co-ECPMA)); (3) poly(2-vinyl naphthalene-co-methyladamantyl methacrylate) (P(2VN-co-MAdMA)); (4) poly(adamantyl methylmethacrylate) (P(AdMMA-co-MAdMA)); and (5) poly(2-vinyl naphthalene-co-methyladamantyl methacrylate-co-triphenylsulfonium 1,1-difluoro-2-(methacryloxyloxy)ethanesulfonate) (P(2VN-co-MAdMA-co-TPS-IMA)). The structures for the five polymers are shown below.

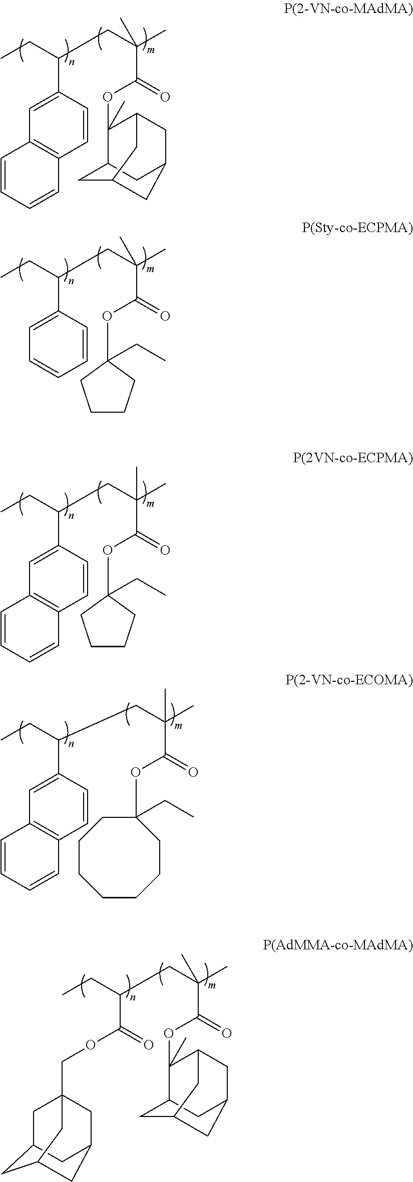

In one embodiment of the invention, the PAG is bound to the polymer backbone and in another embodiment, the PAG is not bound to the polymer. With the latter, the polymer and the PAG are two separate compounds that form a blend. Scheme 1 below depicts a polymer lacking bound PAG groups and Scheme 2 below depicts a polymer having bound PAG groups. Example 2 describes the synthesis of the PAG bound polymer P(2VN-co-MAdMA-co-TPSIMA).

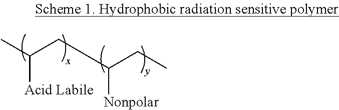

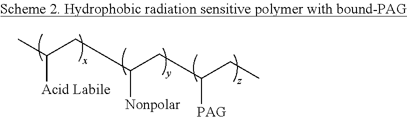

Any suitable PAG can be used in the NTD resists of the present invention. Those of skill in the art will appreciate that any PAG incorporated into the NTD resists described herein should have high thermal stability, i.e., be stable to at least 140° C., so they are not degraded during pre-exposure processing. For PAG-bound polymers, the PAG will be photochemically converted into, for example, a polymer-bound sulfonic acid group, in the areas exposed to the radiation. The PAG, which may be ionic or non-ionic, may be any compound that, upon exposure to radiation, generates a strong acid and is compatible with the other components of the photoresist. Examples of PAGs that may be used with the NTD resists of the present invention include without limitation, sulfonates, onium salts, aromatic diazonium salts, sulfonium salts, diaryliodonium salts and sulfonic acid esters of N-hydroxyamides or N-hydroxyimides. Examples of typical PAGs include the following:

(1) sulfonium salts, such as triphenylsulfonium perfluoromethanesulfonate (triphenylsulfonium triflate), triphenylsulfonium perfluorobutanesulfonate, triphenylsulfonium perfluoropentanesulfonate, triphenylsulfonium perfluorooctanesulfonate, triphenylsulfonium hexafluoroantimonate, triphenylsulfonium hexafluoroarsenate, triphenylsulfonium hexafluorophosphate, triphenylsulfonium bromide, triphenylsulfonium chloride, triphenylsulfonium iodide, 2,4,6-trimethylphenyldiphenylsulfonium perfluorobutanesulfonate, 2,4,6-trimethylphenyldiphenylsulfonium benzenesulfonate, tris(t-butylphenyl)sulfonium perfluorooctane sulfonate, diphenylethylsulfonium chloride, and phenacyldimethylsulfonium chloride;

(2) halonium salts, particularly iodonium salts, including diphenyliodonium perfluoromethanesulfonate (diphenyliodonium triflate), diphenyliodonium perfluorobutanesulfonate, diphenyliodonium perfluoropentanesulfonate, diphenyliodonium perfluorooctanesulfonate, diphenyliodonium hexafluoroantimonate, diphenyliodonium hexafluoroarsenate, bis-(t-butylphenyl)iodonium triflate, and bis-(t-butylphenyl)-iodonium camphanylsulfonate;

(3) α,α′-bis-sulfonyl-diazomethanes such as bis(p-toluenesulfonyl)diazomethane, methylsulfonyl p-toluenesulfonyldiazomethane, 1-cyclohexylsulfonyl-1-(1,1-dimethylethylsulfonyl) diazomethane, and bis(cyclohexylsulfonyl)diazomethane;

(4) trifluoromethanesulfonate esters of imides and hydroxyimides, e.g., α-(trifluoromethylsulfonyloxy)-bicyclo[2.2.1]hept-5-ene-2,3-dicarboximide (MDT);

(5) nitrobenzyl sulfonate esters such as 2-nitrobenzyl p-toluenesulfonate, 2,6-dinitrobenzyl p-toluenesulfonate, and 2,4-dinitrobenzyl p-trifluoromethylbenzene sulfonate;

(6) sulfonyloxynaphthalimides such as N-camphorsulfonyloxynaphthalimide and N-pentafluorophenylsulfonyloxynaphthalimide;

(7) pyrogallol derivatives (e.g., trimesylate of pyrogallol);

(8) naphthoquinone-4-diazides;

(9) alkyl disulfones;

(10) s-triazine derivatives, as described in U.S. Pat. No. 4,189,323; and

(11) miscellaneous sulfonic acid generators including t-butylphenyl-α-(p-toluenesulfonyloxy)-acetate, t-butyl-α-(p-toluenesulfonyloxy)acetate, and N-hydroxy-naphthalimide dodecane sulfonate (DDSN), and benzoin tosylate.

Other suitable photoacid generators are disclosed in Reichmanis et al., Chemistry of Materials 3:395 (1991).

In a further embodiment of the invention, the NTD photoresists may include additives, such as base quenchers, sensitizers, or other expedients known in the art. A base quencher in particular may be added to the photoresist formulations to prevent diffusion of acid in unexposed areas. Suitable base quenchers that may be used with the present invention include, without limitation, aliphatic amines, aromatic amines, carboxylates, hydroxides, or combinations thereof. Examples of base quenchers include, without limitation, 2-phenyl benzimidazole; tert-butyl 2-phenyl-1,3-benzodiazole-1-carboxylate; dimethylamino pyridine; 7-diethylamino-4-methyl coumarin (Coumarin 1); tertiary amines; sterically hindered diamine and guanidine bases, such as 1,8-bis(dimethylamino)naphthalene (e.g., PROTON SPONGE®); berberine; and polymeric amines (such as in the PLURONIC® or TETRONIC® series commercially available from BASF). Tetra alkyl ammonium hydroxides or cetyltrimethyl ammonium hydroxide may be used as a base quencher when the PAG is an onium salt

The NTD resists of the present invention are prepared as follows: (a) the hydrophobic polymer-PAG composition described herein is dissolved in a casting solvent; (b) the dissolved composition is coated on a substrate to produce a resist film; (c) optionally, the film is baked to drive off the casting solvent (the post-application bake or PAB); (d) the film is exposed to radiation; (e) optionally, the film is baked (post-exposure bake or PEB); and (f) the film is developed with an organic hydrocarbon solvent (also referred to herein as the “NTD solvent”) that dissolves the unexposed, but not the exposed regions of the film, the latter of which remain to give a negative tone image on the substrate.

The NTD resists of the present invention typically comprise the-polar acid-stable group in the range of about 10-70 mol % of the resist composition and the non-polar acid-labile group in the range of about 30-70 mol % of the resist composition, with the combination of the acid-stable and acid-labile moieties being least 80 mol % of the resist composition. The PAG is typically about 1-15 mol % of the resist composition. Table 1 (Example 1) shows the polymer ratio of resists prepared as described herein. Examples 3-5 describe resist formulations made from the following polymers: P(2VN-co-MAdMA); P(AdMMA-co-MAdMA); and the PAG-bound P(2VN-co-MAdMA-co-TPS-IMA), respectively.

The casting solvent used in the preparation of the resist formulation (referenced in step (a) above), is typically a heterocarbon solvent, such as for example, 1-methoxy-2-propyl-acetate (PGMEA), cyclohexanone, ethyl lactate, and the like.

In a preferred embodiment of the invention, the static water contact angle of the resist film before exposure is at least 80°. FIG. 8 shows that the resist film prepared from the P(2VN-co-MAdMA) polymer of Example 1 has a static water contact angle of 85.3°.

On exposure of the resist film (with, for example, DUV radiation at 248 and 193 nm, EUV radiation at 13.5 nm, e-beam radiation or ion beam radiation), the PAG produces a strong acid that deprotects the acid labile group during post exposure processing to yield a highly polar group. This process renders the initially soluble exposed areas of the film insoluble in the organic hydrocarbon solvent developer described herein.

The exposed NTD resists of the present invention are developed using nonpolar aromatic or aliphatic solvents, which have the following characteristics: a hydrogen bonding component (δₕ) between 0.0 and 5.0; and δᵥ between 10.0 and 30.0, preferably, between 15.0 and 25.0, wherein δᵥ is represented by the following formula:

δᵥ=(δ_{d}²+δₚ²)½

wherein (δ_{d}) is the dispersive component of the solvent and (δₚ) is the polarity component of the solvent. Examples of solvents that may be used to prepare the NTD resists of the present invention include without limitation, mesitylene (1,3,5-trimethylbenzene), xylene, toluene, decane, hexane, dodecane, and the like.

It is to be understood by those of skill in the art that the NTD solvent described herein will typically be different from the casting solvent discussed previously. While the casting solvent may dissolve both the exposed and unexposed areas of the NTD resist films described herein, the NTD solvents will only dissolve the unexposed areas of the NTD resist films of the present invention.

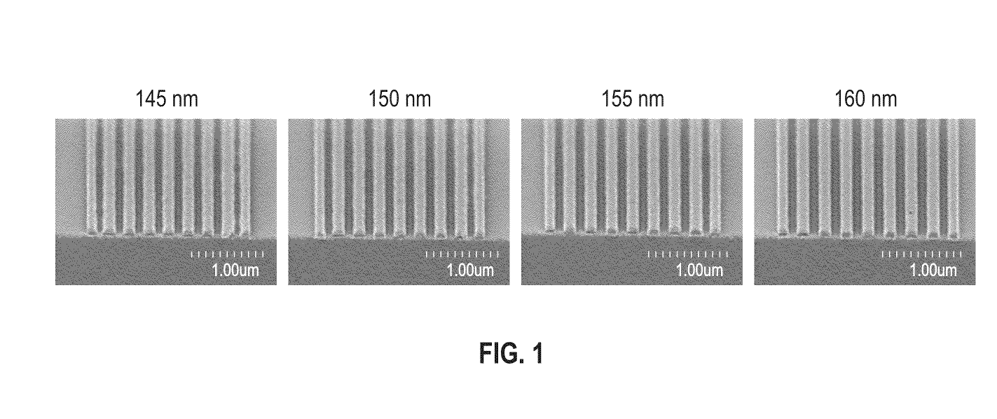

FIGS. 1-7 show that the NTD resists of Examples 3-5 produce high resolution images at all currently used exposures.

FIG. 1 shows SEM images of the hydrophobic P(2VN-co-MAdMA) resist film of Example 3 exposed with DUV 248 nm radiation and developed with the organic hydrocarbon solvent mesitylene. As shown therein, the resist film shows high resolution patterned 1:1 L images from 145 nm to 160 nm.

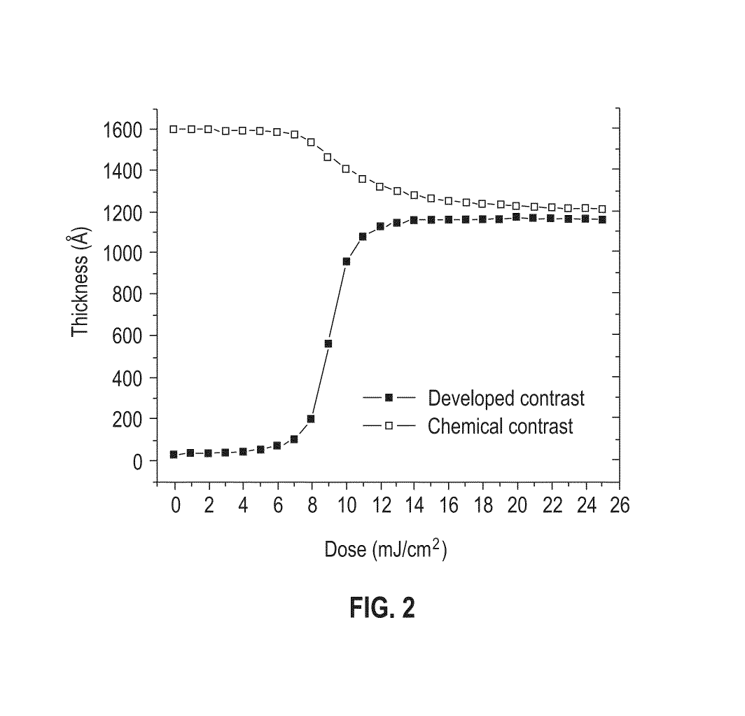

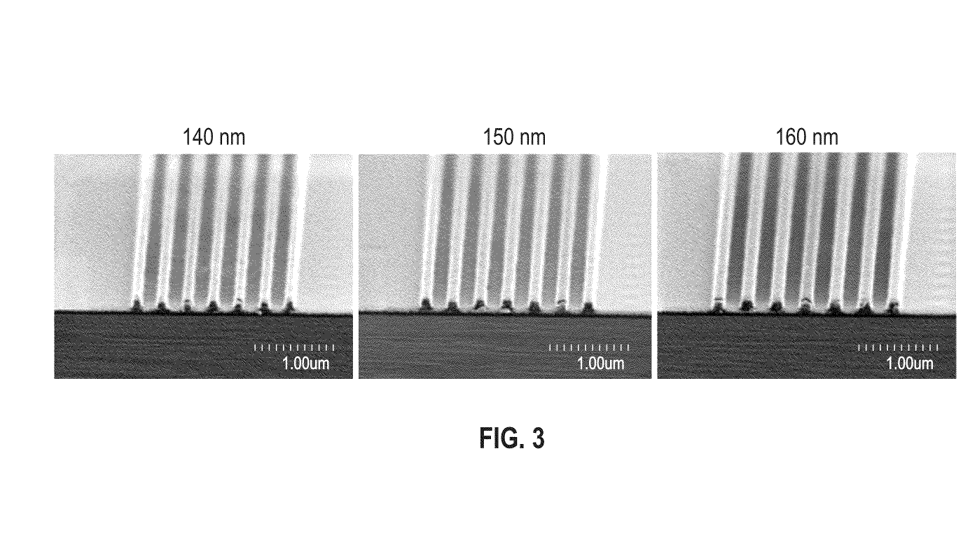

FIG. 2 shows the 193 nm contrast curves for the hydrophobic P(AdMMA-co-MAdMA) resist film of Example 4 prepared with a PEB of 120° C. for 60 sec and developed with mesitylene. The chemical contrast curve shows the thickness of the resist at the PEB step of the resist preparation procedure (see, Experimental for a description of the resist preparation procedures). The development contrast curve, which shows the thickness of the resist following development with mesitylene, displays the characteristic upward slope of a negative resist. The meeting of the two slopes at approximately 1200 Å (120 nm) shows that the NTD procedure of the present invention at 193 nm exposure results in no top loss on the resist. Because the mesitylene is only dissolving the unexposed regions of the resist and not the exposed regions, the result is a highly defined 193 nm resist. FIG. 3 shows SEM images of the P(AdMMA-co-MAdMA) resist film exposed with 193 nm radiation and developed with mesitylene. As shown therein, the resist shows high resolution patterned 1:1 L/S images at 140 nm (A), 150 nm (B), and 160 nm (C).

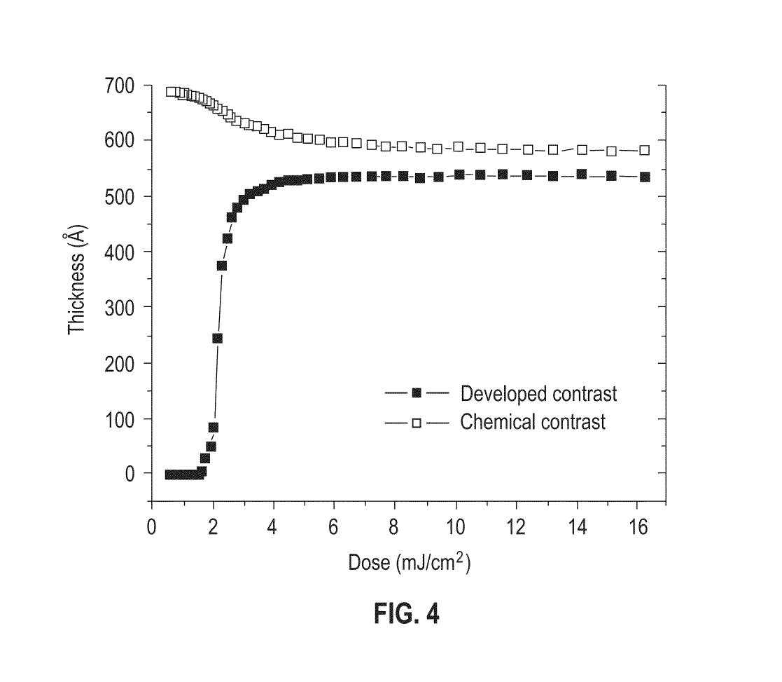

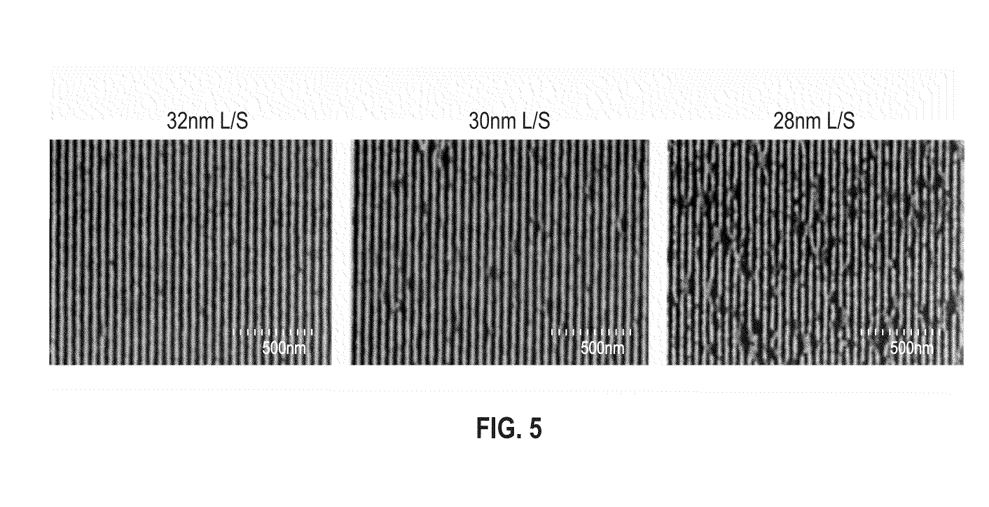

FIG. 4 shows the EUV 13.5 nm contrast curves for the hydrophobic PAG-bound P(2VN-co-MAdMA-co-TPS-IMA) resist film of Example 5 prepared with a PEB of 140° for 60 sec and developed with mesitylene. The meeting of the two slopes between 550 to 600 Å (55-60 nm) shows that the NTD procedure of the present invention at EUV exposure results in minimal top loss on the resist. FIG. 5 shows SEM images of the P(2VN-co-MAdMA-co-TPS-IMA) resist film exposed with EUV radiation and developed with mesitylene. As shown therein, the resist shows high resolution patterned 1:1 L/S images at 32 nm and resolution remains acceptable at values as low as 28 nm.

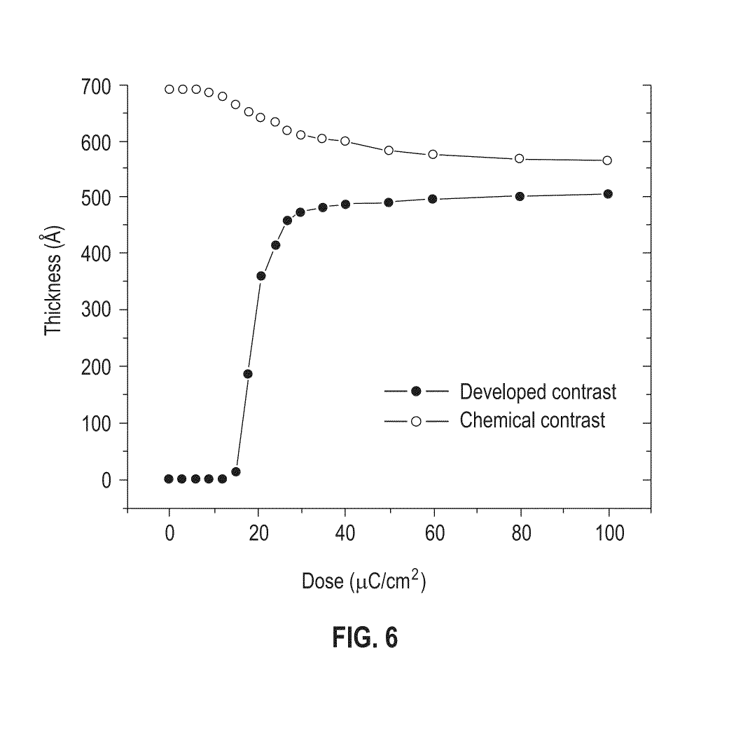

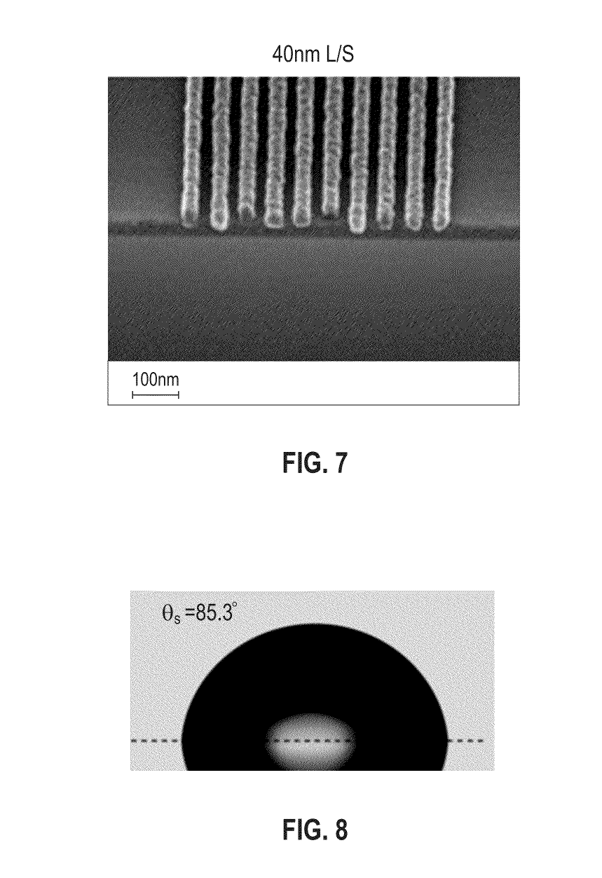

FIG. 6 shows the e-beam contrast curves for the hydrophobic PAG-bound P(2VN-co-MAdMA-co-TPS-IMA) resist film of Example 5 prepared with a PEB of 140° for 60 sec and developed with mesitylene. The meeting of the two slopes between 500 to 550 Å (50-55 nm) shows that the NTD procedure of the present invention at e-beam exposure results in minimal top loss on the resist. FIG. 7 shows a cross sectional SEM images of the P(2VN-co-MAdMA-co-TPS-IMA) resist film exposed with e-beam radiation and developed with mesitylene. As shown therein, the resist shows high resolution patterned 1:1 L/S images at 40 nm.

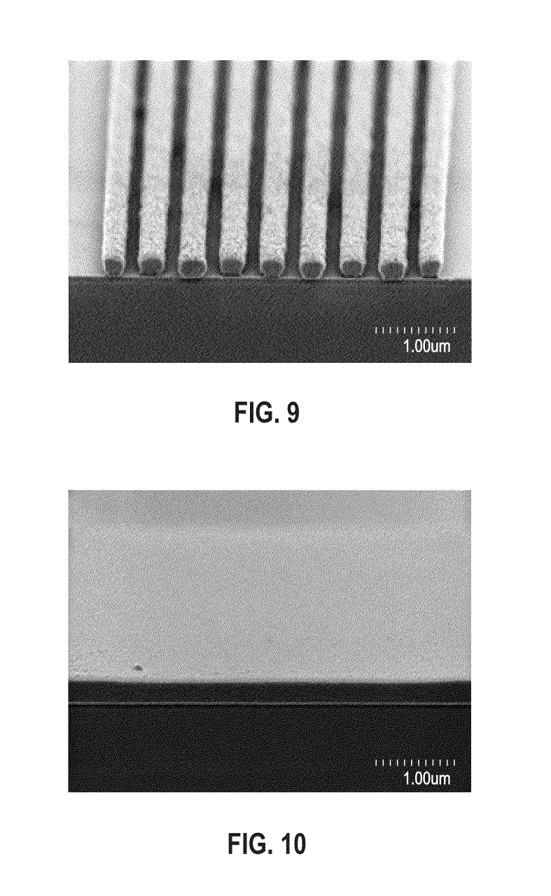

Comparative Example 6 and FIGS. 9 and 10 show that resists prepared from the PAG-bound P(2VN-co-MAdMA-co-TPS-IMA) polymer of Example 5 is soluble in the NTD solvent mesitylene (FIG. 9), but not in 0.26 N TMAH (the standard PTR developer used in the industry) (FIG. 10).

It is to be understood that while the invention has been described in conjunction with the embodiments set forth above, the foregoing description as well as the examples that follow are intended to illustrate and not limit the scope of the invention. Further, it is to be understood that the embodiments and examples set forth herein are not exhaustive and that modifications and variations of the invention will be apparent to those of ordinary skill in the art without departing from the scope and spirit of the invention.

All patents and publications mentioned herein are incorporated by reference in their entireties.

### EXPERIMENTAL

The following examples are intended to provide those of ordinary skill in the art with a complete disclosure and description of how to prepare and use the compositions disclosed and claimed herein. Efforts have been made to ensure accuracy with respect to numbers (e.g., amounts, temperature, etc.), but allowance should be made for the possibility of errors and deviations. Unless indicated otherwise, parts are parts by weight, temperature is in ° C. and pressure is at or near atmospheric. Additionally, all starting materials were obtained commercially or were synthesized using known procedures.

All the monomers reported here are known and purchased from commercial sources or synthesized using known procedures. Where appropriate, the following techniques and equipment were used in the Examples: ¹H and ¹³C NMR spectra were obtained at room temperature on an Avance 400 spectrometer. Quantitative ¹³C NMR was run at room temperature in deuterated chloroform in an inverse-gated ¹H-decoupled mode using Cr(acac)₃ as a relaxation agent on an Avance 400 spectrometer. Thermo-gravimetric analysis (TGA) was performed at a heating rate of 10° C./min in N₂ on a TA Instrument Hi-Res TGA 2950 Thermogravimetric Analyzer. Differential scanning calorimetry (DSC) was performed at a heating rate of 5° C./min on a TA Instruments DSC 2920 modulated differential scanning calorimeter. Molecular weights were measured in tetrahydrofuran (THF) on a Waters Model 150 chromatograph relative to polystyrene standards. Following is a listing of the molecules that were used to prepare the photoresists described in the Examples.

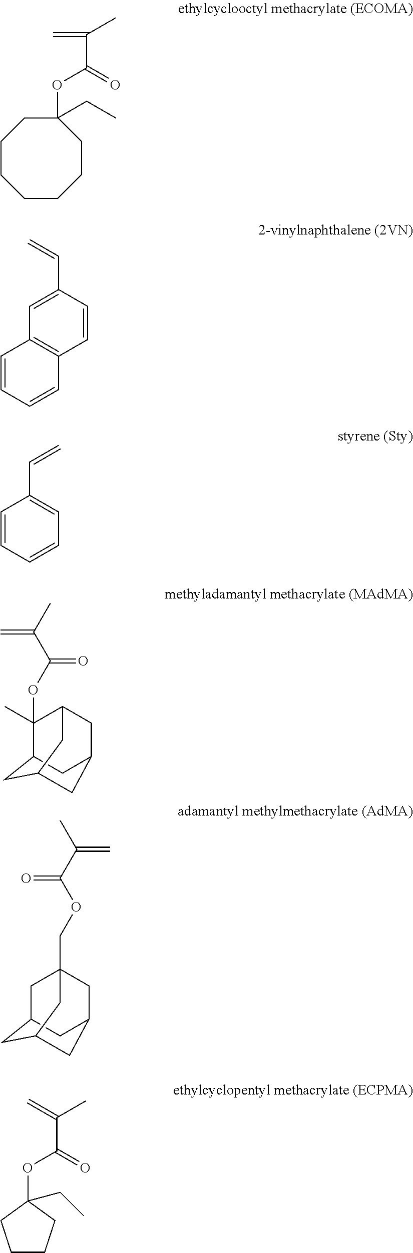

All resist solutions were filtered through a 0.2 micrometer (μm) TEFLON® (E.I. Du Pont de Nemours & Co., Wilmington, Del.) filter prior to spin casting at 3000 rpm for 30 sec. Following is a description of the procedures used in the Examples.

DEEP ULTRAVIOLET (DUV) EXPOSURE: A silicon substrate with a 63 nm thick Brewer Science DUV42P ARC® anti-reflective coating was coated with 1200 Å of a NTD resist composition in a casting solvent. The film was baked (PAB) at 120° C. for 1 minute to drive off the casting solvent. The film was then imagewise exposed at DUV (248 nm; dose 21-24 mJ/cm2) on a 248 nm ASML 5500 stepper (0.61 NA) using a dark field chrome on gas (COG) mask. The film was then baked (PEB) at 120° C. for 1 minute and developed with mesitylene.

193 NM EXPOSURE: A silicon substrate with a 78 nm thick Brewer Science AR29 ARC® anti-reflective coating was coated with 1200 Å of a NTD resist composition in a casting solvent. The film was baked (PAB) at 120° C. for 1 minute to drive off the casting solvent. The film was then exposed at 193 nm (dose 21-24 mJ/cm2) on an ISI-Mini Stepper (0.60 NA). The film was then baked (PEB) at 120° C. for 1 minute and developed with mesitylene for 30 sec.

E-BEAM EXPOSURE: A silicon substrate with a 63 nm thick Brewer Science DUV42P ARC® anti-reflective coating was coated with 600 Å of a NTD resist composition in a casting solvent. The film was baked (PAB) at 120° C. for 1 minute to drive off the casting solvent. Dose 110-130 μC/cm². Electron beam exposure was performed using a Vistec VB6 at 100 keV energy, 0.5 nA current, and 15 nm spot size (Gaussian shape beam).

EUV EXPOSURE: A silicon substrate with a 63 nm thick Brewer Science DUV42P ARC® anti-reflective coating was coated with 500 Å of a NTD resist composition in a casting solvent. The film was baked (PAB) at 120° C. for 1 minute to drive off the casting solvent. Dose 12-14 mJ/cm². Exposure at EUV (13.5 nm) was performed on the SEMATECH Berkeley Microfield Exposure Tool (0.3 NA) at the Advanced Light Source at Lawrence Berkeley National Laboratory.

### Example 1

### Synthesis of Poly(2-Vinyl Naphthalene-Co-Methyl Adamantyl Methacrylate) (P(2VN-co-MAdMA))

2-vinyl naphthalene (2VN) (1.00 g, 6.48 mmole), methyl adamantyl methacrylate (MAdMA) (1.52 g, 6.48 mmole), and 7.5 grams of toluene were placed in a round bottom flask equipped with a condenser and a nitrogen inlet. 2,2′-Azobisisobutyronitrile (AIBN) (085 mg, 0.51 mmole) and 1-dodecanethiol (78 mg, 0.38 mole) were added to the solution and stirred until dissolved. The solution was then degassed using four vacuum/nitrogen purges, the contents were heated at 70° C. for 18 hours, and the solution was added drop wise into methanol (400 mL). The precipitated polymer was filtered (using a frit), washed twice with methanol (100 mL), and dried under vacuum at 60° C. The finished product had the following characteristics: Feed Ratio=50:50; Yield=1.30 grams; Molecular Weight (Mw)=4100; Polydispersity (PDI)=1.60; Glass Transition Temperature (Tg)=120° C.; and Product Ratio by NMR=58:42.

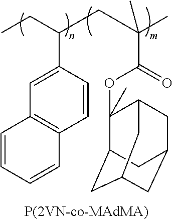

Other polymers including Poly(2VN-co-ECOMA) and Poly(2VN-co-ECPMA), Poly(Sty-co-ECPMA), Poly(AdMMA-co-MAdMA) were synthesized similarly, with only the feed ratio being changed. Details of the polymers are provided in Table 1.

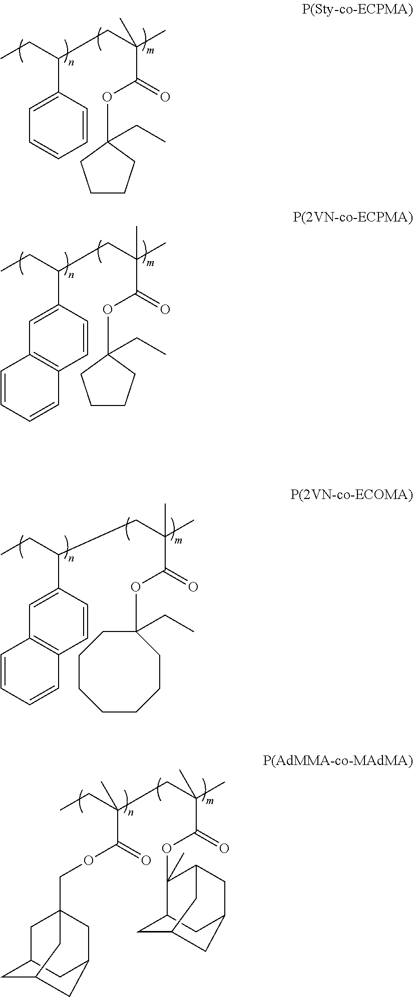

TABLE 1

| | | PRODUCT | | | |
|---|---|---|---|---|---|
| | FEED | RATIO | | | |
| POLYMER | RATIO | BY NMR | Mw | PDI | Tg |
| P(2VN-co-ECOMA) | 60:40 | 65:35 | 4500 | 1.62 | |
| P(2VN-co-ECPMA) | 50:50 | 61:39 | 4290 | 1.66 | 78 |
| P(Sty-co-ECPMA) | 60:40 | 61:39 | 5640 | 1.54 | 65 |
| P(AdMMA-co-MAdMA) | 50:50 | 46:54 | 3960 | 1.64 | 153 |

### Example 2

### Bound PAG Polymer

### Synthesis of Poly(2-Vinyl Naphthalene-Co-Methyl Adamantyl Methacrylate-Co-Triphenylsulfonium 1,1-Difluoro-2-(Methacryloyloxy)Ethanesulfonate) (P(2VN-co-MAdMA-co-TPS-IMA)

2-vinyl naphthalene (2VN) (1.00 g, 6.48 mmole), methyl adamantyl methacrylate (MAdMA) (1.52 g, 6.48 mmole), triphenylsulfonium 1,1-difluoro-2-(methacryloyloxy)ethanesulfonate (TPS-IMA), (0.19 g 0.40 mmole) and 8.0 grams of methyl ethyl ketone (MEK) were placed in a round bottom flask equipped with a condenser and a nitrogen inlet. 2,2′-Azobisisobutyronitrile (AIBN) (87 mg, 0.53 mmole) was added to the solution and stirred until dissolved. The solution was then degassed using four vacuum/nitrogen purges, the contents were heated at 70° C. for 18 hours, and the solution was added drop wise into methanol (400 mL). The precipitated polymer was filtered (using a frit), washed twice with methanol (100 mL), and dried under vacuum at 60° C. The finished product had the following characteristics: Feed Ratio=50:50; Yield=1.0 grams; Mw=2500; PDI=1.56; Tg=152° C.; and Product Ratio by NMR=58:40:2.

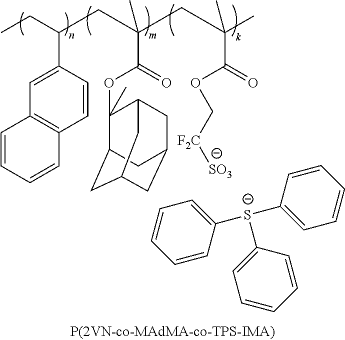

### Example 3

### Resist Formulation for P(2VN-Co-MAdMA)

P(2VN-co-MAdMA) (0.1 grams), PAG (5 mg), and a base additive were dissolved in propylene glycol monomethyl ether acetate (PGMEA, 1.9 grams). The solution was filtered through a 0.2 μm TEFLON® filter.

### Example 4

### Resists Formulation for P(AdMMA-co-MAdMA)

P(AdMMA-co-MAdMA) (0.1 grams), PAG (5 mg) and a base additive were dissolved in 1.9 g of cyclohexanone. The solution was filtered through a 0.2 μm TEFLON® filter.

### Example 5

### Resist Formulation for P(2VN-co-MAdMA-co-TPS-IMA)

P(2VN-co-MAdMA-co-TPS-IMA) (0.1 grams) and a base additive were dissolved in 1.9 g cyclohexanone. The solution was filtered through a 0.2 μm TEFLON® filter.

### Example 6

### Comparative Example

This example demonstrates that the hydrophobic resists described herein are only developable using NTD conditions, i.e., only developable using a nonpolar aromatic or aliphatic solvent, and that the NTD resist films, upon exposure to UV radiation and PEB, are not soluble in 0.26 N TMAH.

FIG. 9 shows an SEM image of a resist film developed using the bound-PAG polymer of Example 2 with mesitylene as the solvent (NTD conditions). DUV imaging: 160 nm L/S; no base; and 12 mJ/cm² dose. The SEM image shows that the exposed area of the resist film remained undeveloped while the unexposed area was developed.

FIG. 10 shows an SEM image of a resist film developed using the bound-PAG polymer of Example 2 with 0.26 N TMAH as the developer (standard PTR conditions). DUV imaging: 160 nm L/S; no base; and 28 mJ/cm² dose. The SEM image shows that the 0.26 N TMAH failed to develop the film, including the exposed areas. FIG. 10 demonstrates that the NTD resist of Example 2 did not behave like a standard NTD resist, i.e., a resist that forms a positive tone image when developed in 0.26 N TMAH.

1. A photoresist composition comprising:
(a) a hydrophobic polymer comprising (i) at least one non-polar acid-stable group; and (ii) at least one non-polar acid-labile group, wherein the hydrophobic polymer does not have any polar groups; and
(b) a photo acid generator (PAG),
wherein upon patternwise exposure of the composition to radiation, the PAG dissociates to form a photo acid that reacts with the at least one non-polar acid-labile group resulting in increased polarity of the hydrophobic polymer, and further wherein upon development of the exposed composition with an organic hydrocarbon solvent, unexposed areas of the composition dissolve and exposed areas of the photoresist composition remain to give a negative tone image.

2. The composition of claim 1, wherein the at least one non-polar acid-stable group of (a)(i) is selected from the group consisting of Formula I and Formula II: 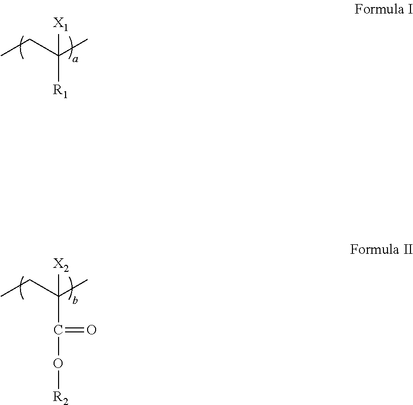
wherein
X1 and X2 are independently selected from the group consisting of H, CH₃, and CF₃;
R1 is selected from the group consisting of aromatic hydrocarbons and substituted aromatic hydrocarbons;
R2 is selected from the group consisting of aromatic hydrocarbons, aliphatic hydrocarbons, substituted aromatic hydrocarbons, substituted aliphatic hydrocarbons, and silicon containing compounds; and
a and b are independently a non-zero integer >1.

3. The composition of claim 1, wherein the at least one non-polar acid-labile group of (a)(ii) is selected from the group consisting of Formula III and Formula IV: 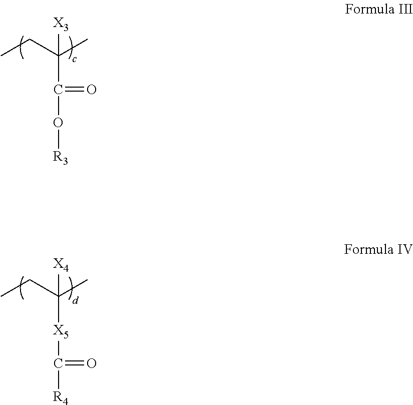
wherein
X3 and X4 are independently selected from the group consisting of H, CH₃, and CF₃;
X5 is a linking group selected from the group consisting of a single bond, aromatic groups, aliphatic groups, substituted aromatic groups, and substituted aliphatic groups.
R3 and R4 are independent acid labile groups; and
c and d are independently a non-zero integer >1.

4. The composition of claim 1, wherein the at least non-polar one acid stable group of (a)(i) is selected from the group consisting of 2-vinylnapthylene, styrene, adamantyl methylmethacrylate, and isobornyl methacrylate.

5. The composition of claim 1, wherein the at least non-polar one acid labile group of (a)(ii) is selected from the group consisting of ethylcyclopentyl methacrylate (ECPMA), methyl adamantyl methacrylate (MAdMA), ethyl cyclohexyl methacrylate (ECHMA), ethyl cyclooctyl methacrylate (ECOMA), and ethyl adamantyl methacrylate (EAdMA).

6. The composition of claim 1, wherein the hydrophobic polymer of (a) is selected from the group consisting of poly(2-vinyl naphthalene-co-ethylcyclopentyl methacrylate) (P(2VN-co-ECPMA)); poly(styrene-co-ethylcyclopentyl methacrylate) (P(Sty-co-ECPMA)); poly(2-vinyl naphthalene-co-methyladamantyl methacrylate) (P(2VN-co-MAdMA)); poly(adamantyl methylmethacrylate)-co-methyladamantyl methacrylate) (P(AdMMA-co-MAdMA)); and poly(2-vinyl naphthalene-co-methyladamantyl methacrylate-co-triphenylsulfonium 1,1-difluoro-2-(methacryloxyloxy)ethanesulfonate) (P(2VN-co-MAdMA-co-TPS-IMA)).

7. The composition of claim 1, wherein the non-polar acid-stable group of (a)(i) is present in the composition in the range of about 10-70 mol %.

8. The composition of claim 1, wherein the non-polar acid-labile group of (a)(ii) is present in the composition in the range of about 30-70 mol %.

9. The composition of claim 1, wherein the combination of the non-polar acid-stable group of (a)(i) and the non-polar acid-labile group of (a)(ii) is present in the composition in the range of at least 80 mol %.

10. The composition of claim 1, wherein the PAG is present in the composition in the range of about 1-15 mol %.

11. The composition of claim 1, wherein the PAG is either bound or unbound to the polymer.

12. The composition of claim 1, wherein the PAG is both bound and unbound to the polymer.

13. The composition of claim 1, wherein the photoresist composition is exposed with radiation selected from the group consisting of deep ultraviolet (DUV) radiation, extreme ultraviolet (EUV) radiation, electron beam (e-beam) radiation, and ion beam radiation.

14. The composition of claim 1, wherein the organic solvent is a non-polar aliphatic solvent and/or a non-polar aromatic solvent.

15. The composition of claim 1, wherein the organic hydrocarbon solvent is selected from the group consisting of mesitylene, xylene, toluene, decane, hexane, and dodecane.

16. The composition of claim 1, wherein exposed regions of the photoresist composition are not developable in an aqueous base developer.

17. The composition of claim 1, wherein the photoresist composition has a static water contact angle of at least 80°.

18. A method comprising the steps of:
(a) dissolving the hydrophobic polymer-PAG composition of claim 1 in a casting solvent;
(b) coating a substrate with the dissolved composition of step (a) to produce a resist film;
(c) optionally baking the resist film of step (b);
(d) exposing the resist film to radiation;
(e) optionally baking the resist film of step (d); and
(f) developing the resist film with an organic hydrocarbon solvent to dissolve unexposed regions of the film.

19. The method of claim 18, wherein the PAG is bound to the polymer.

20. The method of claim 18, wherein the PAG is not bound to the polymer.

21. The method of claim 18, wherein the radiation is selected from the group consisting of deep ultraviolet (DUV) radiation, extreme ultraviolet (EUV) radiation, electron beam (e-beam) radiation, and ion-beam radiation.

22. The method of claim 18, wherein the organic solvent is a non-polar aliphatic solvent and/or a non-polar aromatic solvent.

23. The method of claim 22, wherein the organic hydrocarbon solvent is selected from the group consisting of mesitylene, xylene, toluene, decane, hexane, and dodecane.

24. The method of claim 18, wherein exposed regions of the resist film are not developable in an aqueous base developer.

25. The method claim 18, wherein the photoresist composition has a static water contact angle of at least 80°.

26. A photoresist composition, comprising:
(a) a hydrophobic polymer comprising (i) at least one non-polar acid-stable moiety and (ii) at least one non-polar moiety capable of increasing polarity of the composition by action of an acid; and
(b) a photo acid generator (PAG),
wherein upon patternwise exposure of the composition to radiation, exposed regions of the composition are not developable in 0.26 N TMAH developer.

27. The composition of claim 26, wherein the PAG is bound to the polymer.

28. The composition of claim 26, wherein the PAG is not bound to the polymer.

29. The composition of claim 26, wherein the exposed composition can be developed to form a negative tone image with an organic hydrocarbon solvent.

30. The composition of claim 29, wherein the organic hydrocarbon solvent is a non-polar aliphatic solvent and/or non-polar aromatic solvent.

31. The composition of claim 26, wherein the at least one non-polar acid-stable group of (a)(i) is selected from the group consisting of Formula I and Formula II: 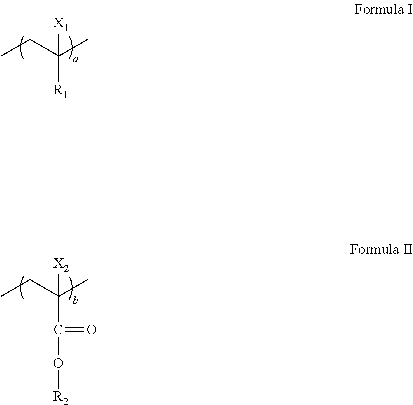
wherein
X1 and X2 are independently selected from the group consisting of H, CH₃, and CF₃;
R1 is selected from the group consisting of aromatic hydrocarbons and substituted aromatic hydrocarbons;
R2 is selected from the group consisting of aromatic hydrocarbons, aliphatic hydrocarbons, substituted aromatic hydrocarbons, substituted aliphatic hydrocarbons, and silicon containing compounds; and
a and b are independently a non-zero integer >1.

32. The composition of claim 26, wherein the at least one non-polar acid-labile group of (a)(ii) is selected from the group consisting of Formula III and Formula IV: 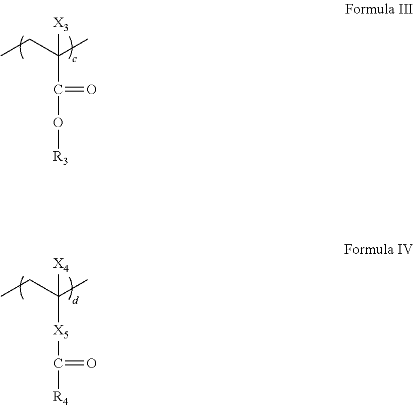
wherein
X3 and X4 are independently selected from the group consisting of H, CH₃, and CF₃;
X5 is a linking group selected from the group consisting of a single bond, aromatic groups, aliphatic groups, substituted aromatic groups, and substituted aliphatic groups.
R3 and R4 are independent acid labile groups; and
c and d are independently a non-zero integer >1.

33. The composition of claim 26, wherein the hydrophobic polymer of (a) is selected from the group consisting of poly(2-vinyl naphthalene-co-ethylcyclopentyl methacrylate) (P(2VN-co-ECPMA)); poly(styrene-co-ethylcyclopentyl methacrylate) (P(Sty-co-ECPMA)); poly(2-vinyl naphthalene-co-methyladamantyl methacrylate) (P(2VN-co-MAdMA)); poly(adamantyl methylmethacrylate)-co-methyladamantyl methacrylate) (P(AdMMA-co-MAdMA)); and poly(2-vinyl naphthalene-co-methyladamantyl methacrylate-co-triphenylsulfonium 1,1-difluoro-2-(methacryloxyloxy)ethanesulfonate) (P(2VN-co-MAdMA-co-TPS-IMA)).

34. A method comprising the steps of:
(a) dissolving the hydrophobic polymer-PAG composition of claim 26 in a casting solvent;
(b) coating a substrate with the dissolved composition of step (a) to produce a resist film;
(c) optionally baking the resist film of step (b);
(d) exposing the resist film to radiation;
(e) optionally baking the resist film of step (d); and
(f) developing the resist film with an organic hydrocarbon solvent to dissolve unexposed regions of the film.
